(19) United States
(12) Patent Application Publication
(10) Pub. No.: US 2026/0066227 A1
(43) Pub. Date: Mar. 5, 2026

(54) FILM DEPOSITION METHOD, ELECTRONIC DEVICE FOR PERFORMING METHOD AND FILM DEPOSITION DEVICE

(71) Applicant: SAMSUNG ELECTRONICS CO., LTD., Suwon-si (KR)

(72) Inventors: Minjae OH, Suwon-si (KR); Ik Soo KIM, Suwon-si (KR)

(73) Assignee: SAMSUNG ELECTRONICS CO., LTD., Suwon-si (KR)

(21) Appl. No.: 19/091,333

(22) Filed: Mar. 26, 2025

(30) Foreign Application Priority Data
Sep. 5, 2024 (KR) 10-2024-0120700

(51) Int. Cl. H01J 37/32; C23C 16/455; C23C 16/458

(52) U.S. Cl. CPC H01J 37/32183; C23C 16/45557; C23C 16/45565; C23C 16/4586; H01J 37/32697; H01J 2237/3321

(57) ABSTRACT

Provided is a film deposition method including: supplying a first gas to an inner space of a chamber using a shower head; generating plasma in the inner space of the chamber by applying radio frequency (RF) power to a susceptor, wherein a substrate is on a surface of the susceptor, and the RF power is applied to the susceptor during a first time period; applying bias power to the shower head in a second time period; supplying a second gas and a precursor to the inner space of the chamber using the shower head; and causing a film to be deposited on the substrate by applying the RF power to the susceptor.

### CROSS-REFERENCE TO RELATED APPLICATION

This application is based on and claims priority to Korean Patent Application No. 10-2024-0120700, filed on Sep. 5, 2024, in the Korean Intellectual Property Office, the disclosure of which is incorporated herein by reference in its entirety.

### BACKGROUND

### 1. Field

The disclosure relates to a film deposition method, an electronic device, and a film deposition device performing the film deposition method.

### 2. Description of the Related Art

A semiconductor device typically has at least one layer on a substrate (for example, a wafer), and at least one layer is deposited on the substrate in the deposition process. The deposition process may generally be divided into chemical vapor deposition (CVD) and physical vapor deposition (PVD). In the case of the CVD, for example, in order to deposit a film, the substrate is placed on a susceptor within a chamber, and a reaction gas is supplied to the surface of the substrate on which a film is to be formed. For example, in the case of the CVD, the reaction gas is introduced into the chamber through a shower head, and the film is formed on the surface of the substrate through a chemical reaction of the reaction gas.

### SUMMARY

Provided is a film deposition method by which a space to be subjected to film deposition is configured based on a power supply device connected to a shower head, and a film is efficiently deposited on a substrate, and provides an electronic device and a film deposition device performing the same.

According to an aspect of the disclosure, a film deposition method includes: supplying a first gas to an inner space of a chamber using a shower head; generating plasma in the inner space of the chamber by applying radio frequency (RF) power to a susceptor, wherein a substrate is on a surface of the susceptor, and the RF power is applied to the susceptor during a first time period; applying bias power to the shower head in a second time period; supplying a second gas and a precursor to the inner space of the chamber using the shower head; and causing a film to be deposited on the substrate by applying the RF power to the susceptor.

According to an aspect of the disclosure, an electronic device includes: memory storing one or more instructions; and at least one processor configured to execute the one or more instructions, wherein the one or more instructions, when executed by the at least one processor, cause the electronic device to: supply a first gas to an inner space of a chamber through a shower head in the inner space, generate plasma in the inner space of the chamber by applying radio frequency (RF) power to a susceptor in the inner space, wherein a substrate is on a surface of the susceptor, and the RF power is applied to the susceptor during a first time period, apply bias power to the shower head during a second time period, supply a second gas and a precursor to the inner space of the chamber through the shower head, and cause a film to be deposited on the substrate by applying the RF power to the susceptor.

According to an aspect of the disclosure, a film deposition device includes: a chamber comprising an inner space; a shower head in the inner space of the chamber, wherein the shower head is configured to discharge at least one of a gas, a reactant, a precursor or any combination thereof into the inner space; a susceptor in the inner space of the chamber, wherein the susceptor is configured to receive a substrate; a first generator that is outside the chamber, wherein the first generator is configured to supply bias power to the shower head; a second generator that is outside the chamber, wherein the second generator is configured to supply radio frequency (RF) power to the susceptor through a matching part; a vacuum pump that is outside the chamber, wherein the vacuum pump is configured to suck at least a portion of a reaction by-product from the inner space of the chamber; a valve in a section of a piping that connects the chamber to the vacuum pump, wherein the valve is configured to adjust an internal pressure of the chamber; memory storing one or more instructions; and at least one processor configured to execute the one or more instructions, wherein the one or more instructions, when executed by the at least one processor, cause the at least one processor to control a time period during which the first generator and the second generator operate.

According to example embodiments, a film deposition device and an electronic device provide a film deposition method in which by applying bias power to a shower head, the direction of movement of at least a portion of a component existing in an inner space of a chamber is controlled, and a film is deposited after a protruding part of a substrate is cut off as the protruding part of the component and the substrate collide, and thus voids are minimized and the film is deposited efficiently.

The present disclosure is not limited to the technical aspects described above. Additional aspects and features of the disclosure may be inferred from the following example embodiments which are described in detail below.

### BRIEF DESCRIPTION OF DRAWINGS

The above and other aspects and features of certain embodiments of the present disclosure will be more apparent from the following description taken in conjunction with the accompanying drawings, in which:

FIG. 1 is a schematic diagram illustrating a film deposition system according to one or more embodiments;

FIG. 2 is a drawing for explaining components of an electronic device and a film deposition device according to one or more embodiments;

FIG. 3 is a drawing for comparing and explaining the differences with the film deposition process according to one or more embodiments;

FIG. 4A is a drawing illustrating a film deposition device controlled by an electronic device according to one or more embodiments;

FIG. 4B is a drawing illustrating a substrate etched by a film deposition device according to one or more embodiments;

FIG. 4C is a drawing illustrating another type of substrate etched by a film deposition device according to one or more embodiments;

FIG. 5 is a drawing for explaining the film deposition process of the substrate according to FIG. 4B and FIG. 4C;

FIG. 6 is a drawing for explaining the sequence of a film deposition method according to one or more embodiments;

FIG. 7 is a flowchart for explaining a film deposition method according to one or more embodiments; and

FIG. 8 is a drawing illustrating components of an electronic device performing a film deposition method according to one or more embodiments.

### DETAILED DESCRIPTION

In the following description, like reference numerals refer to like elements throughout the specification.

Terms used in the example embodiments are selected from currently widely used general terms when possible while considering the functions in the present disclosure. However, the terms may vary depending on the intention or precedent of a person skilled in the art, the emergence of new technology, and the like. Further, in certain cases, there are also terms arbitrarily selected by the applicant, and in the cases, the meaning will be described in detail in the corresponding descriptions. Therefore, the terms used in the present disclosure should be defined based on the meaning of the terms and the contents of the present disclosure, rather than the simple names of the terms.

Throughout the specification, when a part is described as “comprising or including” a component, it does not exclude another component but may further include another component unless otherwise stated. Furthermore, terms such as “ . . . unit,” “ . . . group,” and “ . . . module” described in the specification mean a unit that processes at least one function or operation, which may be implemented as hardware, software, or a combination thereof.

It will be understood that when an element is referred to as being “connected” with or to another element, it can be directly or indirectly connected to the other element, wherein the indirect connection includes “connection via a wireless communication network”.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

Hereinafter, example embodiments of the present disclosure will be described in detail with reference to the accompanying drawings so that those of ordinary skill in the art to which the present disclosure pertains may easily implement them. However, the present disclosure may be implemented in multiple different forms and is not limited to the example embodiments described herein.

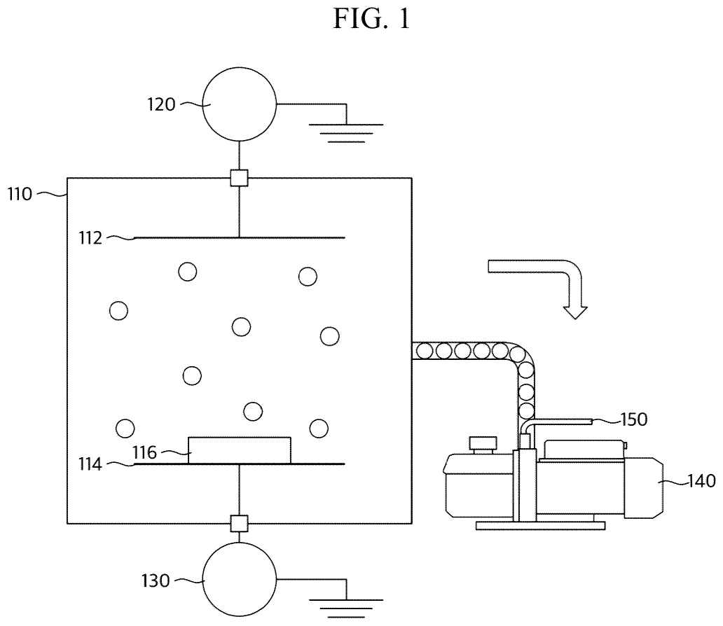

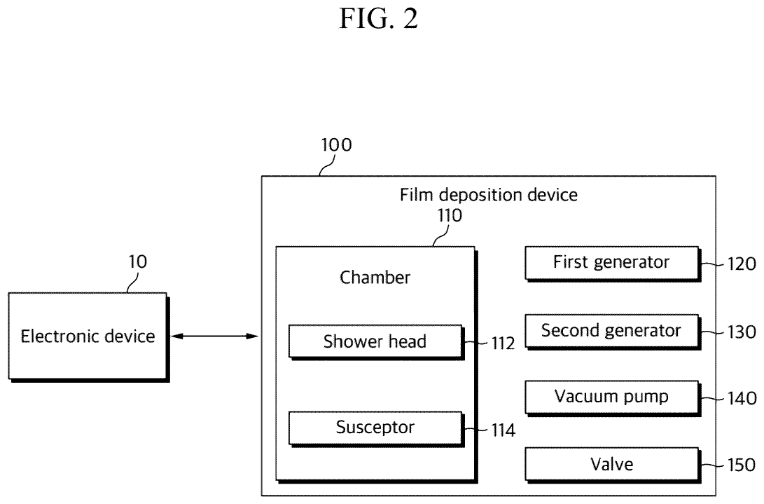

FIG. 1 is a drawing illustrating a film deposition system according to one or more embodiments of the present disclosure, and FIG. 2 is a drawing for explaining components of an electronic device and a film deposition device according to one or more embodiments of the present disclosure.

Referring to FIG. 1 and FIG. 2, a film deposition device 100 may include at least one of a chamber 110, a first generator 120, a second generator 130, a vacuum pump 140 and a valve 150. The film deposition device may be used in a film deposition system.

In one or more embodiments, a shower head 112, a susceptor 114 and a substrate 116 may be arranged in the inner space of the chamber 110.

The chamber 110 may be connected to the vacuum pump 140 positioned outside of the chamber 110 through a pipe inserted into an opening formed on at least one surface.

In one or more embodiments, the shower head 112 may discharge (or supply) various types of reactants into the inner space of the chamber 110. The shower head 112 may be electrically connected to the first generator 120 and may receive DC power from the first generator 120.

In one or more embodiments, the substrate 116 may be placed on one surface of the susceptor 114. The susceptor 114 may be electrically connected to the second generator 130 and may receive radio frequency (RF) power from the second generator 130.

In one or more embodiments, the vacuum pump 140 may be positioned outside the chamber 110 and may suck reaction by-products present in the inner space of the chamber 110. The vacuum pump 140 may suck the reaction by-products inside the chamber 110 through the piping.

In one or more embodiments, the valve 150 may be placed in a section of the pipe connecting the vacuum pump 140 and the chamber 110.

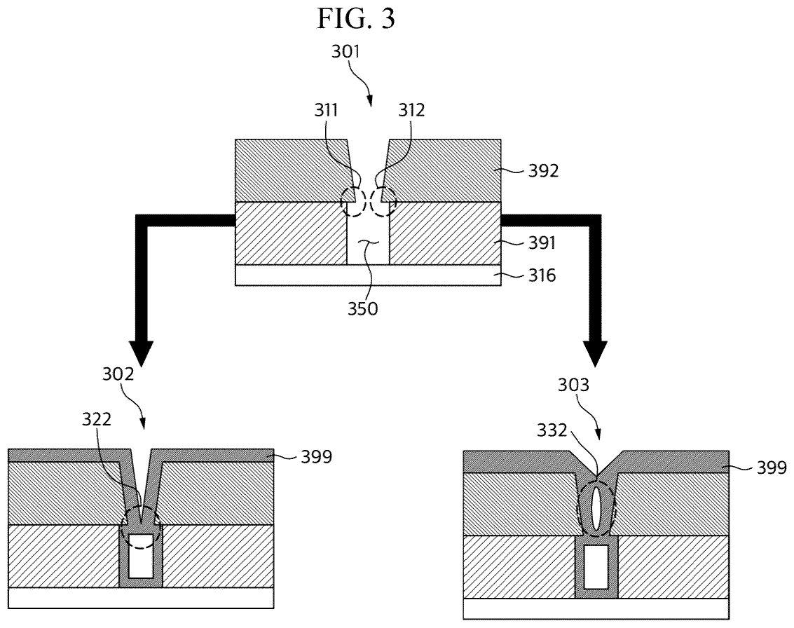

Below, a process based on a film deposition system including the film deposition device 100 as illustrated in FIG. 1 and FIG. 2 is described in which a film is deposited after at least a portion (for example, a first protruding part 311 and a second protruding part 312 of FIG. 3) of the pattern formed on the substrate 116 is cut.

An electronic device 10 may be electrically connected to the film deposition device 100. For example, the electronic device 10 may control operation of at least some of the components included in the film deposition device 100.

The film deposition device 100 may include the chamber 110, the first generator 120, the second generator 130, the vacuum pump 140 and the valve 150.

In one or more embodiments, the chamber 110 may include an inner space that is sealed from the outside, and provide a processing space for a substrate. For example, the chamber 110 may include the shower head 112, the susceptor 114, and a substrate 116.

The shower head 112 is placed at the top of an inner space of the chamber 110, and may be configured to discharge (or supply) at least one of a gas, a reactant, a precursor, and any combination thereof in a downward direction. For example, the shower head 112 may include multiple supply lines for discharging different types of reactants into the inner space of the chamber 110.

The susceptor 114 may be placed at the bottom of the inner space of the chamber 110. For example, a substrate may be placed on one surface of the susceptor 114 facing the shower head 112. For example, the susceptor 114 may include an electrostatic chuck (ESC) and/or a heater provided on one surface. For example, a substrate may be mounted on one surface of the susceptor 114.

A substrate may be a material used in the manufacture of a semiconductor device. For example, the substrate may include at least one of a silicon (Si) wafer, a gallium arsenide (GaAs) wafer, a sapphire (Al₂O₃) wafer, a germanium (Ge) wafer, a gallium nitride (GaN) wafer, a silicon carbide (SiC) wafer, a glass substrate, a ceramic substrate and an interposer. The substrate may be a film whose height-wise length is very small compared to its horizontal length. The above descriptions for the substrate are mere example embodiments, and the example embodiments may be varied in many different example embodiments.

In one or more embodiments, the first generator 120 and the second generator 130 may be positioned outside of the chamber 110, and may include a power supply device that supplies (or applies) power to at least some of the components included in the chamber 110.

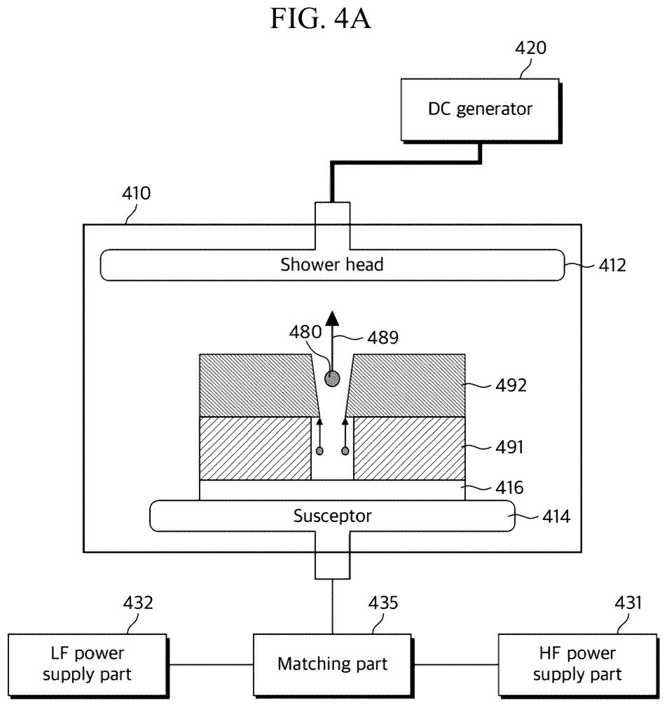

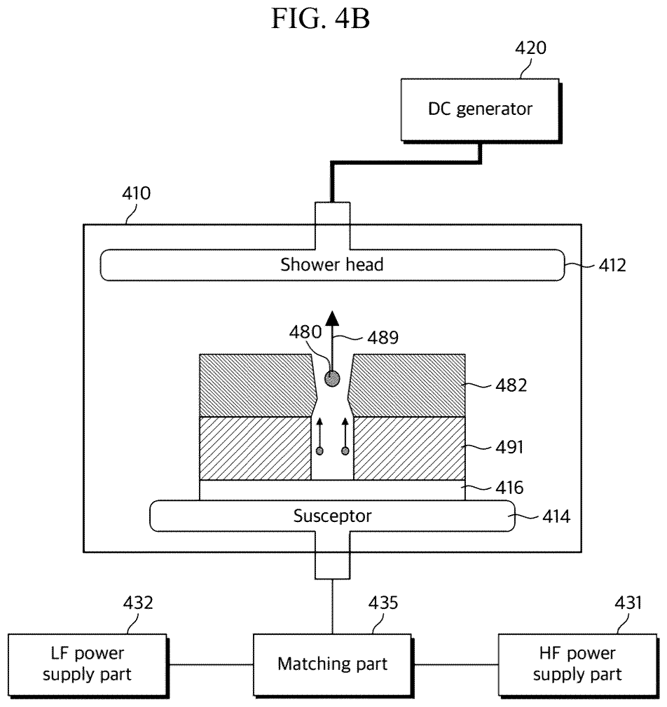

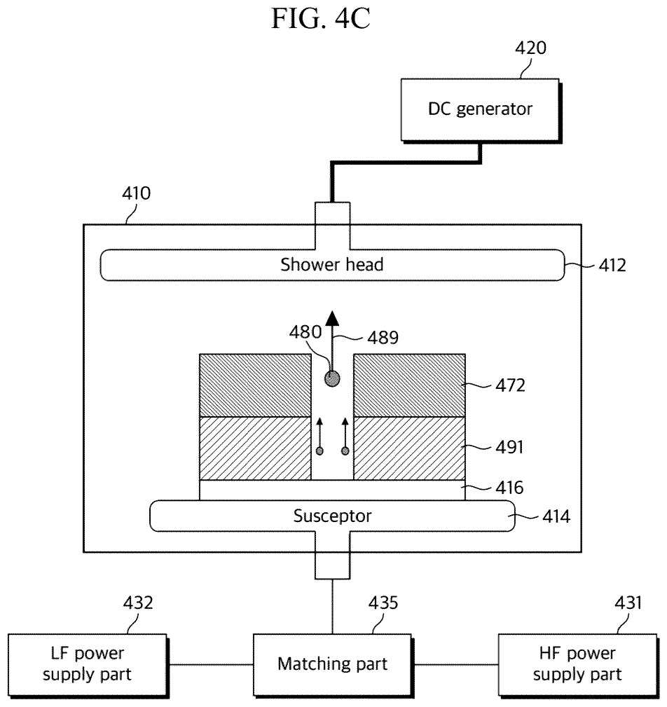

The first generator 120 may be electrically connected to the shower head 112 and may supply power to the shower head 112. The power supplied by the first generator 120 may, in one or more embodiments, be bias power (or direct current (DC) power). In one or more embodiments, the first generator 120 may directly provide power to the shower head 112 without a separate matching part (for example, a matching part 435 of FIG. 4A), unlike the second generator 130.

The second generator 130 may be electrically connected to the susceptor 114 and supply power to the susceptor 114. The power supplied by the second generator 130 may, in one or more embodiments, be RF power (or alternating current (AC) power). In one or more embodiments, the second generator 130 may supply power to the susceptor 114 via a matching part, unlike the first generator 120. In one or more embodiments, the second generator 130 may include a plurality of power supply parts (for example, a high-frequency (HF) power supply part 431 and a low-frequency (LF) power supply part 432 of FIG. 4A). In one or more embodiments, the plurality of power supply parts may be power supply devices that supply power having different frequencies.

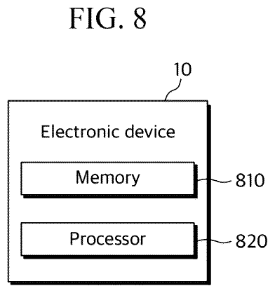

The electronic device 10 may control at least some of the components included in the film deposition device 100 (for example, the shower head 112, the first generator 120, the second generator 130, the vacuum pump 140, and the valve 150) to deposit a film on the substrate. Operations performed by the electronic device 10 described below may be operations performed by a processor 820 of FIG. 8 executing at least one instruction stored in a memory 810.

In one or more embodiments, the electronic device 10 may supply a first gas into the chamber 110 using the shower head 112. The first gas may include at least one of argon (Ar), krypton (Kr), xenon (Xe), and any combination thereof. The electronic device 10 may supply the first supply amount of the first gas to the inner space of the chamber 110 using the shower head 112.

In one or more embodiments, the electronic device 10 may generate plasma in the inner space of the chamber 110 by applying power to the susceptor 114 in the first time period. By using the second generator 130, the electronic device 10 may apply RF power to the susceptor 114 in the first time period through the matching part.

The electronic device 10 may apply RF power to the susceptor 114 using only at least some of the plurality of power supply parts included in the second generator 130. In one or more embodiments, the electronic device 10 may apply RF power supplied from the second generator 130 to the susceptor 114 through the matching part. In one or more embodiments, the electronic device 10 may supply only high-frequency RF power by using only the HF power supply part among the plurality of power supply parts included in the second generator 130 to generate plasma inside the chamber 110.

The first time period may be between 0.1 and 0.3 seconds, but the first time period is not limited thereto.

In one or more embodiments, the electronic device 10 may apply power to the shower head 112 in a second time period.

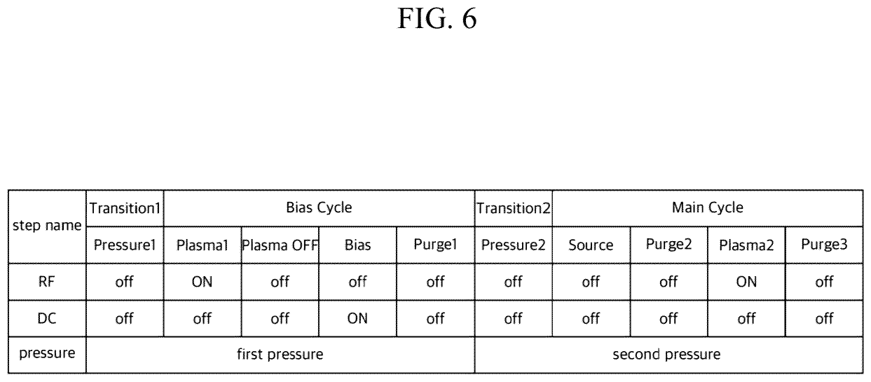

The electronic device 10 may block the supply of RF power through the second generator 130 for at least a period of time in a second time period. In one or more embodiments, the supply of RF power may be cut off in a “Plasma OFF” stage of FIG. 6.

The electronic device 10 may apply bias power (or DC power) to the shower head 112 using the first generator 120. In one or more embodiments, the electronic device 10 may directly apply bias power to the shower head 112 through the first generator 120, unlike the process of applying the RF power to the susceptor 114 through the matching part.

After the first period of time, the electronic device 10 may block RF power applied to the susceptor 114 for at least a portion of the second time period. In one or more embodiments, the electronic device 10 may block RF power for a specified period of time (for example, 0.1 to 0.3 seconds) in the second time period, and apply the bias power to the shower head 112. In one or more embodiments, the electronic device 10 may not apply power to the shower head 112 and the susceptor 114 for a specified period of time, and thus the electronic device 10 may minimize the plasma sheath area of the inner space of the chamber 110 resulting in the increase of the mobility of ions. In one or more embodiments, the specified time period may include a period of time that overlaps the first time period and the second time period.

The second time period may be shorter than the first time period. In one or more embodiments, the second time period may be between 0.1 seconds and 1 second, but the second time period is not limited thereto.

By applying the bias power to the shower head 112, the electronic device 10 may move at least some of the first gas (for example, plasma-formed argon (Ar)) having activation energy in a first direction as the plasma is generated (for example, a first direction 489 of FIG. 4A), where the first direction is from the substrate toward the shower head 112. The protruding part may be cut by at least some of the first gas colliding with the protruding part formed on the substrate during the process of moving the first gas in the first direction.

The protruding part may be a portion that protrudes into the area (or gap) etched in the process where at least one of a plurality of fine patterns formed on a substrate 416 are etched. In one or more embodiments, the protruding part may include at least a portion of a second pattern (for example, the first protruding part 311 and the second protruding part 312) that is protruding further than the first pattern when viewed from the perspective of the substrate looking up toward the shower head 112 (for example, the first direction 489 in FIG. 4A) in an area where the first pattern formed on the substrate (for example, a first pattern 391 of FIG. 3) and the second pattern formed on top of the first pattern (for example, a second pattern 392 of FIG. 3) are joined. In one or more embodiments, the plurality of fine patterns (for example, the first pattern and the second pattern) may include at least one of silicon oxide (SiO₂), silicon nitride (Si₃N₄), polysilicon, and any combination thereof.

The operation of applying RF power to the susceptor 114 in the first time period and the operation of applying bias power to the shower head 112 in the second time period may be operations included in one cycle (for example, a bias cycle of FIG. 6). In one or more embodiments, the electronic device 10 may repeatedly cut the protruding part by repeating operations of the bias cycle for a predefined time or predetermined number of times (for example, 10 to 1,000 times) after applying bias power to the shower head 112 in the second time period. In one or more embodiments, after repeating the operations of the bias cycle a predefined number of times, the electronic device 10 may perform the operations described below.

In one or more embodiments, the electronic device 10 may supply a second gas and a precursor into the chamber 110 using the shower head 112 and apply RF power to the susceptor 114 to deposit a film on the substrate.

The electronic device 10 may control the internal pressure of the chamber 110 by adjusting the tightening strength (or tightening angle) of the valve 150 placed in a section of the pipe connecting the chamber 110 and the vacuum pump 140 just before supplying the second gas and the precursor to the inner space of the chamber.

The electronic device 10 may set the first pressure as the pressure inside the chamber 110 using the valve 150 in the first time period and the second time period (or during the bias cycle).

The electronic device 10 may set the pressure in the inner space of the chamber 110 to second pressure using the valve 150 after the second time period is elapsed (or, after repeating the bias cycle a predefined number of times) and while the film is being deposited on the substrate (or, while the main cycle is repeated). In one or more embodiments, the second pressure may be greater than the first pressure.

The internal pressure of the chamber 110 in the bias cycle may be less than the internal pressure of the chamber 110 in the main cycle. Therefore, in the bias cycle in which the pressure in the inner space of the chamber 110 is relatively low, the distance that molecules move gets relatively greater. Accordingly, the electronic device 10 may cut protruding parts more efficiently in the bias cycle.

The second gas may include at least one of argon (Ar), krypton (Kr), xenon (Xe), and any combination thereof. In one or more embodiments, the electronic device 10 may supply the second supply amount of second gas into the chamber 110 using the shower head 112. In one or more embodiments, the second supply amount may be less than the first supply amount of the first gas. Therefore, in the bias cycle, the number of collisions between molecules in the inner space of the chamber 110 becomes relatively small, and the electronic device 10 may cut the protruding parts more efficiently. In one or more embodiments, the second gas may further contain a reactant (for example, an oxygen-containing gas). In one or more embodiments, the reactant may react with the precursor and transform into a film when RF power is applied to the susceptor 114.

By applying the RF power to the susceptor 114, the electronic device 10 may deposit a film on the substrate based on the reactant and at least some of the precursor adjacent to the substrate moving in the second direction (i.e., from the shower head 112 toward the substrate) opposite to the first direction. In one or more embodiments, the reactant may include oxygen molecules (02). In one or more embodiments, the precursor may include silicon precursor.

The electronic device 10 may minimize the defect rate of the process due to voids by depositing a film on the substrate after cutting the protruding part of the pattern formed on the substrate through a defined number of bias cycles in the first time period and the second time period.

The components illustrated in FIG. 1 and FIG. 2 are mere example embodiments, and the present disclosure is not limited thereto. For example, the film deposition device 100 may further include a processor operatively connected to at least some of the components included in the film deposition device 100. The processor may perform at least some of the operations performed by the electronic device 10 described above.

FIG. 3 is a drawing for explaining a film deposition process in one or more embodiments of the present disclosure.

As shown in stage 301, a plurality of fine patterns may be formed on a substrate 316 in the semiconductor manufacturing process. For example, the substrate 316 may have a plurality of fine patterns formed based on exposure equipment.

In one or more embodiments, the substrate 316 may include the first pattern 391 formed on one surface of the substrate 316 and the second pattern 392 formed on top of the first pattern 391. The electronic device 10 may deposit a film 399 on the substrate 316 according to stage 301 using the film deposition device 100.

In one or more embodiments, a structure as shown at stage 301 may be implemented in a method in which: the first pattern 391 is first transferred onto one surface of the substrate 316; a temporary material of a specified material is filled into a gap 350 formed in the etching process for the first pattern 391; the second pattern 392 is transferred on the top of the first pattern 391; and the etching process is performed on at least a portion of the second pattern 392. During the etching process, a protruding part (the first protruding part 311 and the second protruding part 312) may be formed in the second pattern 392 due to energy loss of the plasma, etc. Due to the protruding part (the first protruding part 311 and the second protruding part 312), problems may occur with reference numerals 302 and 303.

Stage 302 is a drawing illustrating the result of deposition of the film 399 using only power in a specified frequency range (for example, HF power) in the RF power.

In one or more embodiments, at stage 302, in the process of the electronic device 10 depositing the film 399 on the substrate 316, due to the protruding part (the first protruding part 311 and the second protruding part 312), the film 399 may not be deposited to the gap 350 of the first pattern 391. Referring to area 322, in the deposition process, the area between the protruding parts (the first protruding part 311 and the second protruding part 312) may be blocked by the film 399, so the film 399 may not be deposited in the gap 350.

Stage 303 is a drawing illustrating the result of depositing the film 399 using both HF power and LF power in the RF power.

In one or more embodiments, at stage 303, in the process of the electronic device 10 depositing the film 399 on the substrate 316, a cut area may be formed on top of the second pattern 392 by sputtering. Afterward, as the deposition continues, due to the protruding part (the first protruding part 311 and the second protruding part 312), the film 399 may not be deposited to the gap 350 of the first pattern 391, and further, a void 332 may be formed in an area of the second pattern 392.

FIG. 4A is a drawing illustrating a film deposition device controlled by an electronic device according to one or more embodiments.

The film deposition device (for example, the film deposition device 100 of FIG. 2) may include a chamber 410 (for example, the chamber 110 of FIG. 2), a DC generator 420 (for example, the first generator 120 of FIG. 2), the RF generator (the HF power supply part 431 and the LF power supply part 432), and the matching part 435. For example, the RF generator may include the HF power supply part 431 and the LF power supply part 432 that supply power in different frequency ranges. A susceptor 414, a shower head 412, and the substrate 416 having a plurality of patterns (a first pattern 491 and a second pattern 492) formed thereon may be provided in an inner space of the chamber 410.

The components of the film deposition device illustrated in FIG. 4A are mere example embodiments, and the film deposition device is not limited thereto. For example, the film deposition device may further include components such as the vacuum pump 140 and the valve 150 of FIG. 2. For example, the HF power supply part 431, the LF power supply part 432 and the matching part 435 may be implemented as a single module.

In one or more embodiments, the chamber 410 may include an inner space that is sealed from the outside. For example, the shower head 412, the susceptor 414, and the substrate 416 may be provided in the inner space of the chamber 410.

The shower head 412 may be electrically connected to the DC generator 420 to receive DC power. The shower head 412 is placed at the top of the inner space of the chamber 410, and may be configured to discharge (or supply) at least one of a gas, a reactant, a precursor or any combination thereof, in a downward direction. The shower head 412 may include a plurality of supply lines for discharging different types of reactants into the inner space of the chamber 410.

The susceptor 414 may be electrically connected to the RF generator (the HF power supply part 431 and the LF power supply part 432) and the matching part 435 to receive RF power. The RF generator (the HF power supply part 431 and the LF power supply part 432) may supply RF power to the susceptor 414 through the matching part 435. The susceptor 414 may be placed at the bottom of the inner space of the chamber 410. The substrate 416 may be placed on a surface of the susceptor 414 facing the shower head 412. The susceptor 414 may include an ESC and/or a heater provided on one surface.

The substrate 416 may be a material used in the manufacture of semiconductor devices. For example, the substrate 416 may include a pattern wafer. The substrate 416 may include a plurality of patterns (the first pattern 491 and the second pattern 492) formed on one surface facing the shower head 412. The substrate 416 may include the first pattern 491 formed on one surface facing the shower head 412 and the second pattern 492 formed on top of the first pattern 491. The second pattern 492 may include the protruding part (for example, the first protruding part 311 and the second protruding part 312 of FIG. 3) protruding more than the first pattern when viewed in the direction toward the shower head 412 in the area that is joined to the first pattern 491. The first pattern 491 and the second pattern 492 may include at least one of silicon oxide (SiO₂), silicon nitride (Si₃N₄), polysilicon, and any combination thereof.

In one or more embodiments, the DC generator 420 and the RF generator (the HF power supply part 431 and the LF power supply part 432) may be placed outside of the chamber 410, and may include a power supply device that supplies (or applies) power to at least some of the components included in the chamber 410.

The DC generator 420 is electrically connected to the shower head 412 and may supply power to the shower head 412. The power supplied by the DC generator 420 may, in one or more embodiments, be bias power (or DC power). In one or more embodiments, the DC generator 420 may supply power to the shower head 412 directly without going through a separate matching part 435, unlike the RF generator (the HF power supply part 431 and the LF power supply part 432).

An RF generator may be electrically connected to the susceptor 414 and may supply power to the susceptor 414. In one or more embodiments, the RF generator (the HF power supply part 431 and the LF power supply part 432) may include the HF power supply part 431 and the LF power supply part 432 that supply power in different frequency ranges. In one or more embodiments, the HF power supply part 431 may supply HF power with a frequency band of 3 to 30 MHz to the susceptor 414. In one or more embodiments, the LF power supply part 432 may supply LF power with a frequency band of 30 to 300 kHz to the susceptor 414. The power supplied by the RF generator (the HF power supply part 431 and the LF power supply part 432) may, in one or more embodiments, be RF power (or AC power). In one or more embodiments, the RF generator (the HF power supply part 431 and the LF power supply part 432) may supply power to the susceptor 414 through the matching part 435, unlike the DC generator 420. In one or more embodiments, the matching part 435 may be a component that increases the supply efficiency of RF power by matching the impedance of the chamber 410 with the impedance of the RF generator (the HF power supply part 431 and the LF power supply part 432).

The film deposition device may deposit a film on the substrate 416 based on the control by the electronic device (for example, the electronic device 10 of FIG. 1) that is electrically connected to at least some of the components included in the film deposition device (for example, the shower head 412, the DC generator 420, the HF power supply part 431, the LF power supply part 432, the matching part 435 and a valve).

In one or more embodiments, the electronic device may supply first gas to the inner space of the chamber 410 using the shower head 412. For example, the first gas may include at least one of argon (Ar), krypton (Kr), xenon (Xe), and any combination thereof. The film deposition device may supply first gas equivalent to the first supply amount to the inner space of the chamber 410 using the shower head 412.

Before supplying the first gas to the inner space of the chamber 410, the electronic device may set the pressure inside the chamber 410 to the first pressure using a valve (for example, the valve 150 in FIG. 2) that is placed in a section of the piping connecting the chamber 410 and a vacuum pump (for example, the vacuum pump 140 in FIG. 2).

In one or more embodiments, the electronic device may generate plasma inside the chamber 410 by applying power to the susceptor 414 in the first time period. The electronic device may apply RF power to the susceptor 414 for the first time period through the matching part 435 using the RF generator (the HF power supply part 431 and the LF power supply part 432).

The electronic device may apply RF power to the susceptor 414 using only at least some of a plurality of power supply parts included in the RF generator (the HF power supply part 431 and the LF power supply part 432). In one or more embodiments, the electronic device may generate plasma in the inner space of the chamber 410 by applying only HF power to the susceptor 414 from the RF power by using only the HF power supply part 431 among the plurality of power supply parts included in the RF generator (the HF power supply part 431 and the LF power supply part 432).

The first time period may be between 0.1 and 0.3 second, but the figures are mere example embodiments, and the first time period is not limited thereto.

In one or more embodiments, the electronic device cuts off the supply of RF power through the RF generator (the HF power supply part 431 and the LF power supply part 432) (or, the HF power supply part 431) after the first time period is elapsed, and the electronic device may cut a protruding part (for example, the first protruding part 311 and the second protruding part 312 of FIG. 3) of a pattern formed on the substrate 416 by applying power to the shower head 412 in a second time period.

The electronic device may apply bias power (or DC power) to the shower head 412 using the DC generator 420. In one or more embodiments, the electronic device may directly apply bias power to the shower head 412 via the DC generator 420, unlike the process of applying RF power to the susceptor 414 through the matching part 435.

The electronic device may block RF power applied to the susceptor 414 after the first time period is elapsed. In one or more embodiments, the electronic device may block RF power for at least a period of time (or a specified period) in the second time period after the first time period is elapsed, and apply bias power to the shower head 412. In one or more embodiments, not applying power to the shower head 412 and the susceptor 414 for a specified period of time, the electronic device may increase the mobility of ions by minimizing the plasma sheath area of the inner space of the chamber 410.

The second time period may be longer than the first time period. In another example embodiment, the second time period may be between 0.1 and 1 second, but the figures are mere example embodiments, and the second time period is not limited thereto.

The electronic device may apply bias power to the shower head 412 to cause at least some of a first gas 480 (for example, plasma-activated argon (Ar)) that has activation energy as plasma is generated to move in the first direction 489 from the substrate 416 toward the shower head 412. For example, at least some of the first gas 480 may collide with the protruding part formed on the substrate 416 while moving in the first direction 489, thereby cutting off the protruding part.

The protruding part may be a portion that protrudes into the area (or gap) etched in the process where at least some of the plurality of fine patterns formed on the substrate 416 are etched. In one or more embodiments, the protruding part may include at least a portion of the second pattern 492 (for example, the first protruding part 311 and the second protruding part 312) protruding more than the first pattern 491 when viewed in the direction toward the shower head 412, in an area where the first pattern 491 formed on the substrate 416 and the second pattern 492 formed on top of the first pattern 491 are bonded.

The electronic device may block both RF power and bias power for a predetermined time (for example, 0.1 to 0.3 seconds) after a second time period is elapsed, and the electronic device may discharge reaction by-products in the inner space of the chamber 410 to the outside of the chamber 410 using a vacuum pump (for example, the vacuum pump 140 of FIG. 2). When the predetermined time is elapsed, in one or more embodiments, the electronic device may supply a second gas and precursor to the inner space of the chamber 410 using the shower head 412 for film deposition and apply RF power to the susceptor 414.

One cycle (for example, the bias cycle of FIG. 6) may include applying RF power to the susceptor 414 in the first time period, applying bias power to the shower head 112 in the second time period, and discharging reaction by-products outside the chamber 410 for a predefined period of time. In one or more embodiments, the electronic device may repeatedly cut the protruding part by repeating the operations of the above-described bias cycle a predefined number of times (for example, 10 to 1,000 times). In one or more embodiments, after repeating the bias cycle operations a predefined number of times, the electronic device may supply the second gas and the precursor to the inner space of the chamber 410 for film deposition and apply RF power to the susceptor 414.

Before supplying the second gas to the inner space of the chamber 410, the electronic device may set the pressure in the inner space of the chamber 410 to a second pressure using a valve placed in a section of the piping connecting the chamber 410 and the vacuum pump. For example, the second pressure may be greater than the first pressure.

The operation of depositing a film on the substrate 416 by the electronic device may be replaced with the description of FIG. 2 described above.

FIG. 4B is a drawing illustrating a substrate etched by a film deposition device according to one or more embodiments of the present disclosure.

FIG. 4C is a drawing illustrating another type of substrate etched by a film deposition device according to one or more embodiments of the present disclosure.

Referring to FIG. 4B, according to one or more embodiments, a protruding part of a second pattern 482 among the plurality of fine patterns formed on the substrate 416 may be partially cut off upon collision with at least some of the first gas 480. By repeating the bias cycle of FIG. 6 described later, the electronic device may further cut the remaining protruding part according to FIG. 4B.

Referring to FIG. 4C, according to one or more embodiments, the protruding part of a second pattern 472 may be completely cut off upon collision with at least some of the first gas 480. As the electronic device repeats the bias cycle a predefined number of times, at least some of the first gas 480 may move repeatedly in the first direction 489 and in this process, as at least some of the first gas 480 continues to collide with the protruding part, the protruding part may be completely cut off, as illustrated in FIG. 4C.

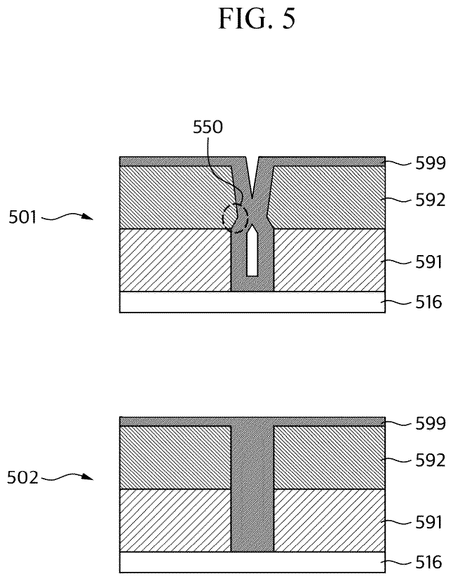

According to one or more embodiments, by the electronic device depositing a film on the substrate 416 according to FIG. 4B and FIG. 4C, respectively, deposition results according to stages 501 and 502 of FIG. 5 below may be obtained.

FIG. 5 is a drawing for explaining the film deposition process of the substrate according to FIG. 4B and FIG. 4C.

In one or more embodiments, by repeatedly performs a bias cycle a predefined number of times, an electronic device (for example, the electronic device 10 of FIG. 1 and FIG. 2) may cut a protruding part (for example, the first protruding part 311 and the second protruding part 312 of FIG. 3) of some of a plurality of fine patterns (a first pattern 591 and a second pattern 592) formed on a substrate 516, and then, deposit a film 599 on the substrate 516, such as stages 501 or 502. The drawing according to stage 501 may illustrate a state in which the film 599 is deposited on the substrate 516 from which a portion (for example, a protruding part) of the second pattern 592 is cut off, as illustrated in FIG. 4B. The drawing according to stage 502 may illustrate a state in which the film 599 is deposited on the substrate 516 from which a portion of the second pattern 592 is further cut (or completely cut), as illustrated in FIG. 4C.

In one or more embodiments, according to stage 501, the electronic device may deposit the film 599 on an area adjacent to the first pattern 591 and the second pattern 592 formed on one surface of the substrate 516.

In one or more embodiments, the second pattern 592 may include a protruding part that protrudes more than the first pattern 591 when viewed from below in the area where the second pattern 592 is joined to the first pattern 591.

Stage 501 is a drawing illustrating the result of depositing the film 599 after partially cutting off the protruding part of the second pattern 592 based on a predefined number of bias cycles of an electronic device.

As the electronic device repeatedly performs the bias cycle a predefined number of times to cut off some of the protruding part of the second pattern 592, a cut area 550 may be generated where the corner of the protruding part is cut off. The electronic device may deposit relatively more film 599 inside the gap due to the cut area 550 compared to the deposition results of reference numerals 302 and 303 in FIG. 3.

Stage 502 is a drawing illustrating the result of depositing the film 599 after cutting all protruding parts of the second pattern 592 based on a predefined number of bias cycles of the electronic device.

As the electronic device repeatedly performs the bias cycle a predefined number of times to cut off the entire protruding part of the second pattern 592, the area where the first pattern 591 and the second pattern 592 are joined may be flattened. The electronic device may efficiently deposit the film 599 over the entire area of the substrate 516 including the gap while minimizing voids by eliminating all protruding parts of the second pattern 592.

FIG. 6 is a drawing for explaining the sequence of a film deposition method according to one or more embodiments of the present disclosure.

An electronic device according to one or more embodiments of the present disclosure (for example, the electronic device 10 of FIG. 2) may sequentially perform a film deposition method based on a recipe according to FIG. 6.

In one or more embodiments, the electronic device may perform the initial wafer placing operation.

In the wafer placing operation, the electronic device may secure a substrate (wafer) to a susceptor (for example, the susceptor 114 of FIG. 2). In one or more embodiments, the susceptor may include at least one of an ESC, a heater, or any combination thereof.

In one or more embodiments, the electronic device may perform a Transition 1 (Pressure 1) stage when the substrate is placed on the susceptor.

In the Transition 1 (Pressure 1) stage, the electronic device may set the internal pressure of the chamber to the first pressure by controlling the tightening strength (or tightening angle) of a valve placed in a section of the pipe connecting the chamber and the vacuum pump.

In the Transition 1 (Pressure 1) stage, the electronic device may supply the first gas to the inner space of the chamber using a shower head. The first gas may, in one or more embodiments, include at least one of argon (Ar), krypton (Kr), xenon (Xe), and any combination thereof.

In one or more embodiments, the electronic device may perform the bias cycle after setting the internal pressure of the chamber to the first pressure through the Transition 1 (Pressure 1) stage. The bias cycle may be performed repeatedly a first number of times, predefined by the user or developer. The internal pressure of the chamber may be maintained at the first pressure while the bias cycle is performed. The amount of first gas supplied to the chamber inner space while the bias cycle is performed may be defined as the first supply amount.

In one or more embodiments, the electronic device may perform a Plasma 1 stage of the bias cycle.

In the Plasma 1 stage of the bias cycle, the electronic device may supply first gas to the inner space of the chamber using the shower head. The first gas may, in one or more embodiments, include at least one of argon (Ar), krypton (Kr), xenon (Xe), and any combination thereof.

In the Plasma 1 stage of the bias cycle, the electronic device may apply some of the RF power (for example, HF power) to a susceptor provided inside the chamber during the first time period. The HF power may, in one or more embodiments, be applied to the susceptor via a matching part.

As HF power is applied to the susceptor, in one or more embodiments, plasma may be generated in the inner space of the chamber.

In one or more embodiments, an electronic device may perform the Plasma OFF stage of the bias cycle.

In the Plasma OFF stage of the bias cycle, the electronic device may continuously supply the first gas to the inner space of the chamber using the shower head.

In the Plasma OFF stage of the bias cycle, the electronic device may block the supply of HF power to the susceptor. The electronic device may increase ion mobility by minimizing the plasma sheath area in the inner space of the chamber by not applying power to the film deposition device through the Plasma OFF stage.

In one or more embodiments, the electronic device may perform a Bias stage of the bias cycle.

In the Bias stage of the bias cycle, the electronic device may continuously supply the first gas to the inner space of the chamber using the shower head.

In the Bias stage of the bias cycle, the electronic device may block the supply of RF power to the susceptor and apply bias power to at least some components of the film deposition device in a second time period. In one or more embodiments, the electronic device may apply bias power (or DC power) to the shower head using a DC generator. As a result of the bias power being applied to the shower head, the plasma generated in the Plasma 1 stage (or the first gas with activation energy) may move from the susceptor toward the shower head, and thus the protruding part of the pattern formed on the substrate may be cut off.

In one or more embodiments, the electronic device may perform a Purge 1 stage of the bias cycle.

In the Purge 1 stage of the bias cycle, the electronic device may continuously supply the first gas to the inner space of the chamber using the shower head.

In the Purge 1 stage of the bias cycle, the electronic device may block RF power and bias power to the susceptor and shower head, respectively.

In the Purge 1 stage of the bias cycle, the electronic device may discharge reaction by-products in the inner space of the chamber, including by-products generated in the etching process in the Bias stage, using a vacuum pump.

When the Purge 1 stage of the bias cycle is completed, the electronic device may perform the bias cycle repeatedly a first number of times predefined by the user starting from the Plasma 1 stage.

In one or more embodiments, the electronic device may perform a Transition 2 (Pressure 2) stage after performing the bias cycle the predefined first number of times.

In the Transition 2 (Pressure 2) stage, the electronic device may set the internal pressure of the chamber to the second pressure by adjusting the tightening strength (or tightening angle) of a valve placed in a section of the pipe connecting the chamber and the vacuum pump. The second pressure may, in one or more embodiments, be greater than the first pressure set in the Transition 1 (Pressure 1) stage.

In the Transition 2 (Pressure 2) stage, the electronic device may supply the first gas and the reactant to the inner space of the chamber using the shower head. The first gas may, in one or more embodiments, include at least one of argon (Ar), krypton (Kr), xenon (Xe), and any combination thereof. The reactant may, in one or more embodiments, include an oxygen-containing gas.

In one or more embodiments, the electronic device may perform the main cycle after setting the internal pressure of the chamber to the second pressure in the Transition 2 (Pressure 2) stage. The main cycle may be repeated a second number of times, predefined by the user or developer. The predefined second number of times may be greater than the predefined first number of times. While the main cycle is being performed, the internal pressure of the chamber may be maintained at the second pressure. The supply amount of the second gas provided to the inner space of the chamber in the main cycle may be determined as the second supply amount that is greater than the first supply amount.

In one or more embodiments, the electronic device may perform a Source stage of the main cycle.

In the Source stage of the main cycle, the electronic device may supply at least one of a source gas, a second gas, a reactant, or any combination thereof to the inner space of the chamber using the shower head.

In the Source stage of the main cycle, at least some of the source gas and the second gas may be adsorbed on the substrate.

In one or more embodiments, the electronic device may perform a Purge 2 stage of the main cycle.

In the Purge 2 stage of the main cycle, the electronic device may supply the second gas and the reactant to the inner space of the chamber using the shower head.

In the Purge 2 stage of the main cycle, the electronic device may exhaust source gases and other reaction by-products that are not adsorbed on the substrate outside the chamber using a vacuum pump.

In one or more embodiments, the electronic device may perform a Plasma 2 stage in the may cycle.

In the Plasma 2 stage of the may cycle, the electronic device may supply second gas and reactant to the chamber inner space using the shower head. The second gas may, in one or more embodiments, include at least one of argon (Ar), krypton (Kr), xenon (Xe), and any combination thereof. The second gas may, in one or more embodiments, include a gas having substantially the same composition as the first gas.

In the Plasma 2 stage of the main cycle, the electronic device may apply some of the RF power (for example, HF power and LF power) to a susceptor provided in the inner space of the chamber in the third time period. The RF power may, in one or more embodiments, be applied to the susceptor via a matching part. As RF power is applied to the susceptor, in one or more embodiments, plasma may be generated in the inner space of the chamber.

In the Plasma 2 stage of the main cycle, the reactants present in the inner space of the chamber may react with the precursor adsorbed on the substrate with activation energy and transform into a film.

In one or more embodiments, the electronic device may perform a Purge 3 stage in the main cycle.

In the Purge 3 stage of the main cycle, the electronic device may continuously supply the first gas and the reactant to the inner space of the chamber using the shower head.

In the Purge 3 stage of the main cycle, the electronic device may block RF power and bias power.

In the Purge 3 stage of the main cycle, the electronic device may discharge reaction by-products from the inner space of the chamber, including by-products generated in the film deposition process of the Plasma 2 stage, using a vacuum pump.

When the Purge 3 stage of the main cycle is completed, the electronic device may perform the main cycle repeatedly a second number of times defined by the user in the Source stage.

In one or more embodiments, the electronic device may perform a wafer purging operation after performing the main cycle a predefined second number of times.

In the wafer purging operation, the electronic device may perform an operation of moving a substrate on which film deposition is completed from the inner space of the chamber to the outside.

The values provided herein for the time period, the time, the set pressure and so on with regard to each of the operations are mere examples, and the present disclosure is not limited thereto. The values may be changed within a specified range.

Further, each of the first time period and the second time period may include at least some of the operations included in the bias cycle. For example, the first time period may include the Plasma 1 stage and/or the Plasma OFF stage, and the second time period may include at least some of the Plasma OFF stage, the Bias stage and the Purge 1 stage. In other words, the first time period may overlap the second time period for a certain period.

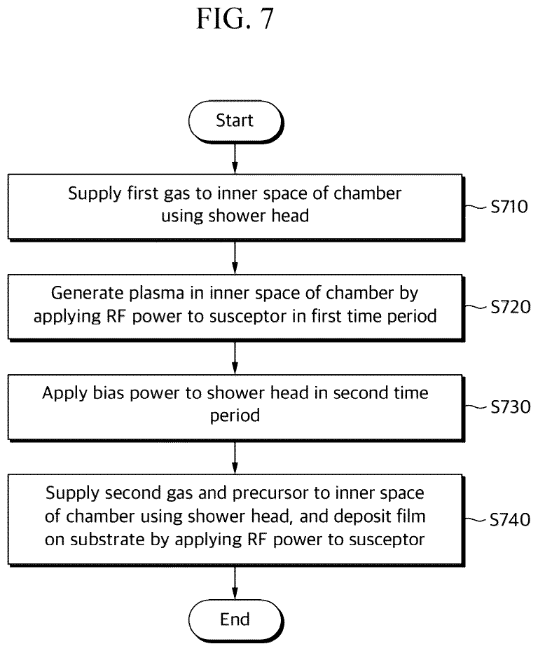

FIG. 7 is a flowchart for explaining a film deposition method according to one or more embodiments of the present disclosure.

According to one or more embodiments, the electronic device (for example, the electronic device 10 of FIG. 2) may perform operations disclosed in FIG. 7. For example, at least some of the components included in the electronic device (for example, the memory 810 and processor 820 of FIG. 8) may be configured to perform the operations of FIG. 7. The electronic device may control the film deposition device to perform the operations described below by transmitting control signals to the film deposition device.

In the example embodiment below, operations S710 to S740 may be performed sequentially, but are not necessarily performed sequentially. For example, the order of each operation may be changed, and at least two of the operations may be performed in parallel. Further, any content that corresponds to or overlaps the content described above in relation to FIG. 7 may be briefly explained or omitted.

In operation S710, the electronic device may supply the first gas to the inner space of the chamber using the shower head.

While supplying the first gas to the inner space of the chamber using the shower head placed in the inner space of the chamber, the electronic device may set the pressure in the inner space of the chamber to the first pressure by controlling the tightening strength (or tightening angle) of a valve placed in a section of the piping connecting the chamber and a vacuum pump placed outside the chamber.

The first gas may include at least one of argon (Ar), krypton (Kr), xenon (Xe), and any combination thereof. The electronic device may supply the first gas equal to the first supply amount to the inner space of the chamber using the shower head.

In operation S720, the electronic device may generate plasma in the inner space of the chamber by applying RF power to a susceptor during a first time period.

During the first time period, the electronic device may apply at least a part of RF power (for example, HF power) to a susceptor positioned at the bottom of the inner space of the chamber.

Using at least a part of the RF generator (for example, the HF power supply part 431 of FIG. 4A), the electronic device may apply HF power to the susceptor via a matching part (for example, the matching part 435 of FIG. 4).

As HF power is applied to the susceptor, the plasma may be generated in the inner space of the chamber.

In operation S730, the electronic device may apply bias power to the shower head in a second time period.

During at least a period of time in the second time period, the electronic device may apply bias power after blocking RF power to the susceptor. In one or more embodiments, the electronic device may increase ion mobility by minimizing the plasma sheath area of the inner space of the chamber by not applying power to the shower head and the susceptor for a specified period of time.

The electronic device may use the DC generator to supply DC power directly to the shower head.

As the bias power is applied to the shower head, as the plasma gas (for example, argon) in the inner space of the chamber moves in the first direction from the susceptor toward the shower head, a protruding part of the pattern formed on the substrate may be cut.

In operation S740, the electronic device may supply the second gas and the precursor to the inner space of the chamber using the shower head, and deposit a film on the substrate by applying RF power to the susceptor.

The electronic device may further supply the reactant. For example, just before supplying the second gas and the precursor, the electronic device may set the pressure in the inner space of the chamber to the second pressure by controlling the tightening strength (or tightening angle) of the valve. In one or more embodiments, the second pressure may be greater than the first pressure.

The second gas may include at least one of argon (Ar), krypton (Kr), xenon (Xe), and any combination thereof. The electronic device may supply the second supply amount of a second gas to the inner space of the chamber using a shower head. In one or more embodiments, the second supply amount may be less than the first supply amount.

By applying the RF power to the susceptor, the electronic device may deposit a film on a substrate based on the reactant moving in a second direction from a shower head toward the substrate and at least some precursor adjacent to (or adsorbed on) the substrate.

In the above example embodiments, although the stages or operations for film deposition are described, example embodiments of the present disclosure are not limited to the stages or operations illustrated with respect to FIG. 6 and the description provided above. For example, the electronic device may selectively block the supply of a specified reactant or gas during at least some of the stage or operations of the bias cycle and the main cycle, or block the supply of the RF power and the DC power.

FIG. 8 is a drawing illustrating components of an electronic device performing a film deposition method according to one or more embodiments.

Referring to FIG. 8, the electronic device 10 may include the memory 810 and the processor 820.

The memory 810 may store instructions or data. For example, the memory 810 may store at least one instruction by which when executed by the processor 820, causes the electronic device 10 performs various operations. For example, a program (or at least one instruction) stored in the memory 810 may be executed by the processor 820.

In one or more embodiments, the memory 810 may store various information associated with the operations of the electronic device 10. For example, the memory 810 may store information about the operation history, operation parameters, performance, etc. of the film deposition of the electronic device 10.

In one or more embodiments, the memory 810 may include a plurality of different types of storage devices. For example, the memory 810 may include volatile and/or nonvolatile storage media. The memory 810 may include at least one of random-access memory (RAM), read only memory (ROM), Embedded Multi-Media Card (eMMC), and any combination thereof.

In one or more embodiments, the memory 810 may be coupled to the processor 820, and the processor 820 may read information from or write information to a storage medium included in the memory 810. For example, the memory 810 and the processor 820 may be implemented as individual components or integrated as a single module.

The processor 820 may be operatively connected to the memory 810. The processor 820 may execute at least one instruction stored in the memory 810. The processor 820 may be a single processor or a plurality of processors. The processor 820 may be implemented as a digital signal processor (DSP) processing digital signals, a microprocessor, and a time controller (TCON). However, the disclosure is not limited thereto, and the processor 820 may include one or more of a central processing unit (CPU), a micro controller unit (MCU), a micro processing unit (MPU), a controller, an application processor (AP), a graphics-processing unit (GPU) or a communication processor (CP), and an advanced reduced instruction set computer (RISC) machines (ARM) processor, or may be defined by the terms. Also, the processor 820 may be implemented as a system on chip (SoC) having a processing algorithm stored therein or large scale integration (LSI), or in the form of a field programmable gate array (FPGA).

In one or more embodiments, the processor 820 may perform a film deposition process using the film deposition device 100 of FIG. 2. The processor 820 is electrically connected to the film deposition device 100, and may transmit and receive various signals with the film deposition device 100.

In one or more embodiments, the processor 820 may cut a protruding part of a pattern formed on a substrate using the film deposition device 100, and deposit a film on a substrate.

For example, the processor 820 may be included in the film deposition device 100, and set the internal pressure of the chamber 110 by adjusting the tightening strength (or tightening angle) of the valve 150 placed in a section of piping connecting the chamber 110 and the vacuum pump 140.

For example, the processor 820 may set internal pressure pf the chamber 110 to the first pressure using the valve 150, and then perform a cutting cycle defined as a bias cycle repeatedly. In one or more embodiments, in the bias cycle, the shower head 112 may supply the first supply amount of first gas (for example, argon-containing gas) to the inner space of the chamber 110 in the first time period, at least some (for example, HF power) of RF power (or AC power) is applied to the susceptor 114 in the second time period, bias power (or DC power) is applied to the shower head 112, the bias power is blocked during at least a period of time in the second time period, and the vacuum pump 140 discharges reaction by-products including by-products generated in the cutting process out of the chamber 110 for a predefined period of time. In one or more embodiments, the bias cycle may be repeated a configurable number of times (for example, 10 to 1,000 times) depending on the user's settings. In other words, the processor 820 may repeat the process (or, the bias cycle) in which bias power is blocked after bias power is applied in the second time period, RF power is applied in the first time period and bias power is applied in the second time period, for a first number of times that is predetermined.

For example, the processor 820 may use the valve 150 to set the internal pressure of the chamber 110 to a second pressure that is greater than the first pressure after repeating the bias cycle a predefined first number of times. In one or more embodiments, the processor 820 may perform a deposition cycle defined as the main cycle repeatedly by setting the chamber 110 internal pressure to the second pressure. In one or more embodiments, in the main cycle, the second gas (for example, argon-containing gas and oxygen-containing gas) is supplied in a second supply amount greater than the first supply amount, after additional source gas is supplied, RF power is applied to the susceptor 114 in a third time period, after the third time period is elapsed, RF power is cut off, and for a predefined period of time, the vacuum pump 140 discharges reaction by-products, including by-products generated in the deposition process, out of the chamber 110. In one or more embodiments, the main cycle may be repeated a set number of times (for example, 10 to 10,000 times) that may be changed by the user's settings. In other words, a predefined second number of times, the processor 820 may repeat a process (or, the main cycle) in which the shower head supplies a second gas and precursor inside the chamber, and RF power is applied to the susceptor for a specific period of time (for example, 0.1 to 0.2 seconds) and then cut off.

The components depicted as included in the electronic device 10 in FIG. 8 are mere example embodiments and the present disclosure is not intended thereto. For example, the electronic device 10 may further include components such as sensors, communication units, interfaces, displays and so on.

The electronic device 10 and the film deposition device 100 according to the above-described example embodiments may include a processor, a memory for storing and executing program data, a permanent storage such as a disk drive, and/or a user interface device such as a communication port, a touch panel, a key and/or a button that communicates with an external device. Methods implemented as software modules or algorithms may be stored in a computer-readable recording medium as computer-readable codes or program instructions executable on the processor. Here, the computer-readable recording medium includes a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

The example embodiments may be represented by functional block elements and various processing steps. The functional blocks may be implemented in any number of hardware and/or software configurations that perform specific functions. For example, one or more embodiments may adopt integrated circuit configurations, such as memory, processing, logic and/or look-up table, that may execute various functions by the control of one or more microprocessors or other control devices. Similar to that elements may be implemented as software programming or software elements, the example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

At least one of the components, elements, modules, units, or the like (collectively “components” in this paragraph) represented by a block or an equivalent indication (collectively “block”) in the above embodiments including the drawings such as FIGS. 1, 2, 4A-4C and 8, for example, HF part, FL part, matching part, susceptor, controller, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

The above-described example embodiments are merely examples, and other embodiments may be implemented within the scope of the claims to be described later.

What is claimed is:

1. A film deposition method comprising:
supplying a first gas to an inner space of a chamber using a shower head;
generating plasma in the inner space of the chamber by applying radio frequency (RF) power to a susceptor, wherein a substrate is on a surface of the susceptor, and the RF power is applied to the susceptor during a first time period;
applying bias power to the shower head in a second time period;
supplying a second gas and a precursor to the inner space of the chamber using the shower head; and
causing a film to be deposited on the substrate by applying the RF power to the susceptor.

2. The film deposition method of claim 1, further comprising:
based on the second time period elapsing, blocking the bias power being delivered to the shower head;
applying the RF power to the susceptor a predetermined number of times during the first time period; and
repeating the applying the bias power to the shower head during the second time period.

3. The film deposition method of claim 1, further comprising:
during the first time period and the second time period, setting a first pressure as an internal pressure of the chamber using a valve; and
after the second time period is elapsed and while causing the film to be deposited on the substrate, setting the internal pressure of the chamber to a second pressure using the valve,
wherein the second pressure is greater than the first pressure, and
wherein the valve is outside the chamber and is in a section of a piping that connects the chamber to a vacuum pump configured to suck at least a portion of a reaction by-product from the inner space of the chamber.

4. The film deposition method of claim 1, wherein a first supply amount of the first gas is less than a second supply amount of the second gas.

5. The film deposition method of claim 1, wherein the generating the plasma comprises applying RF power having a frequency above a predetermined threshold to the susceptor during the first time period.

6. The film deposition method of claim 1, wherein the applying the bias power to the shower head causes at least some of the first gas to move in a first direction from the substrate toward the shower head.

7. The film deposition method of claim 6,
wherein the applying the RF power to the susceptor causes a reactant to move in a second direction that is opposite to the first direction, and
wherein the causing the film to be deposited on the substrate by apply the RF power to the susceptor further comprises depositing the film on the substrate based on the reactant moving in the second direction and at least a portion of the precursor that is adjacent to the substrate.

8. The film deposition method of claim 6, further comprising:
based on a protruding part formed on the substrate being cut by the at least some of the first gas moving in the first direction, supplying the second gas and the precursor to the inner space of the chamber using the shower head,
wherein first pattern is on the substrate and a second pattern is on the first pattern, and
wherein the protruding part comprises at least a portion of the second pattern that protrudes more than the first pattern when viewed from the substrate in a direction toward the shower head.

9. The film deposition method of claim 8, wherein the first pattern and the second pattern comprise at least one of silicon oxide (SiO₂), silicon nitride (Si₃N₄), polysilicon, or any combination thereof.

10. The film deposition method of claim 1,
wherein the bias power is supplied by a first generator and comprises direct current (DC), and
wherein the RF power is supplied by a second generator through a matching part.

11. The film deposition method of claim 1, wherein the susceptor comprises at least one of an electro static chuck (ESC) or a heater on the surface of the susceptor.

12. The film deposition method of claim 1, wherein the applying the bias power further comprises blocking the RF power during at least a portion of the second time period.

13. An electronic device comprising:
memory storing one or more instructions; and
at least one processor configured to execute the one or more instructions,
wherein the one or more instructions, when executed by the at least one processor, cause the electronic device to:
supply a first gas to an inner space of a chamber through a shower head in the inner space,
generate plasma in the inner space of the chamber by applying radio frequency (RF) power to a susceptor in the inner space, wherein a substrate is on a surface of the susceptor, and the RF power is applied to the susceptor during a first time period,
apply bias power to the shower head during a second time period,
supply a second gas and a precursor to the inner space of the chamber through the shower head, and
cause a film to be deposited on the substrate by applying the RF power to the susceptor.

14. The electronic device of claim 13, wherein the one or more instructions, when executed by the at least one processor, cause the electronic device to:
based on the second time period elapsing, block the bias power being delivered to the shower head,
apply the RF power to the susceptor a predetermined number of times during the first time period, and
repeat application of the bias power to the shower head during the second time period.

15. The electronic device of claim 13,
wherein the one or more instructions, when executed by the at least one processor, cause the electronic device to:
during the first time period and the second time period, set a first pressure as an internal pressure of the chamber using a valve, and
after the second time period is elapsed and while causing the film to be deposited on the substrate, set the internal pressure of the chamber to a second pressure using the valve,
wherein the second pressure is greater than the first pressure, and
wherein the valve is outside the chamber and is in a section of a piping that connects the chamber to a vacuum pump configured to suck at least a portion of a reaction by-product from the inner space of the chamber.

16. The electronic device of claim 15, wherein the one or more instructions, when executed by the at least one processor, cause the electronic device to generate the plasma by applying RF power having a frequency above a predetermined threshold to the susceptor during the first time period.

17. The electronic device of claim 13, wherein applying the bias power to the shower head causes at least some of the first gas to move in a first direction from the substrate toward the shower head.

18. The electronic device of claim 17,
wherein applying the RF power to the susceptor causes a reactant to move in a second direction that is opposite to the first direction, and
wherein the one or more instructions, when executed by the at least one processor, cause the electronic device to:
cause the film to be deposited on the substrate by applying the RF power to the susceptor based on the reactant moving in the second direction and at least a portion of the precursor that is adjacent to the substrate.

19. The electronic device of claim 13, wherein the bias power is supplied from a first generator and comprises direct current (DC) power, and
wherein the RF power is supplied by a second generator through a matching part.

20. A film deposition device comprising:
a chamber comprising an inner space;
a shower head in the inner space of the chamber, wherein the shower head is configured to discharge at least one of a gas, a reactant, a precursor or any combination thereof into the inner space;
a susceptor in the inner space of the chamber, wherein the susceptor is configured to receive a substrate;
a first generator that is outside the chamber, wherein the first generator is configured to supply bias power to the shower head;
a second generator that is outside the chamber, wherein the second generator is configured to supply radio frequency (RF) power to the susceptor through a matching part;
a vacuum pump that is outside the chamber, wherein the vacuum pump is configured to suck at least a portion of a reaction by-product from the inner space of the chamber;
a valve in a section of a piping that connects the chamber to the vacuum pump, wherein the valve is configured to adjust an internal pressure of the chamber;
memory storing one or more instructions; and
at least one processor configured to execute the one or more instructions, wherein the one or more instructions, when executed by the at least one processor, cause the at least one processor to control a time period during which the first generator and the second generator operate.
